(19) United States
(12) Patent Application Publication
(10) Pub. No.: US 2023/0159707 A1
(43) Pub. Date: May 25, 2023

(54) COATING COMPOSITION FOR PRODUCING INTERLAYER INSULATION FILM, INTERLAYER INSULATION FILM, SEMICONDUCTOR ELEMENT, AND METHOD FOR PRODUCING INTERLAYER INSULATION FILM

(71) Applicant: DIC Corporation, Tokyo (JP)

(72) Inventors: Takeshi Ibe, Ichihara-shi (JP); Tomoyuki Imada, Ichihara-shi (JP)

(73) Assignee: DIC Corporation, Tokyo (JP)

(21) Appl. No.: 17/801,353

(22) PCT Filed: Feb. 4, 2021
(86) PCT No.: PCT/JP2021/004014

§ 371 Date: Aug. 22, 2022

(30) Foreign Application Priority Data
Feb. 27, 2020 (JP) 2020-031276

(51) Int. Cl. C08G 77/20; C09D 183/04; C08F 299/08; G03F 7/075; H01B 3/44; H01B 19/04; H01B 19/02; B29C 59/02

(52) U.S. Cl. CPC C08G 77/20; B29C 59/022; C08F 299/08; C09D 183/04; G03F 7/0757; H01B 3/44; H01B 19/02; H01B 19/04; B29K 2083/00

(57) ABSTRACT

Provided are a coating composition for producing an interlayer insulation film, the coating composition making it possible to produce an interlayer insulation film patterned and having a high Young’s modulus and a low relative dielectric constant in high throughput, a method for producing the interlayer insulation film, and a semiconductor element including the interlayer insulation film. Specifically, the coating composition for producing the interlayer insulation film includes: a polymerizable compound (A) being a polymerizable silicon compound having two or more polymerizable groups, at least one of the two or more polymerizable groups being a polymerizable group Q expressed by *-O-R-Y (wherein * represents a bond with a silicon atom, R represents a single bond, an unsubstituted or substituted alkylene group having 1 to 12 carbon atoms and optionally containing a heteroatom, or a phenylene group, and Y represents a polymerizable group); and a photopolymerization initiator (B).

### TECHNICAL FIELD

The present invention relates to a coating composition for producing an interlayer insulation film, the interlayer insulation film, a semiconductor element, and a method for producing the interlayer insulation film.

### BACKGROUND ART

Nanoimprinting technology has been attracting the attention as a technology capable of forming a nano-scale fine pattern at a high resolution, and has been expected to be applied to the production of semiconductor integrated circuits, micro electro mechanical systems (MEMS), sensor elements, magnetic recording media, optical devices, optical films for flat panel displays, and the likes. In recent years, nanoimprinting technology has been attracting attention also for reasons other than the resolution. Since nanoimprinting technology is capable of directly forming a complicated three-dimensional pattern without photoresists, etching, or vapor deposition, there is a possibility that device production can be considerably simplified and thereby production costs can be reduced, and therefore application of nanoimprinting technology to various materials having various functions has been investigated.

In the semiconductor field, direct pattern formation on a Spin-On-Glass (SOG) material by using nanoimprint technology has been attracting attention for production of an interlayer insulation film. In an interlayer insulation film including an SOG material, a film having a low dielectric constant and a high Young’s modulus is formed, and therefore high insulation resistance, peeling resistance at a CMP step, and high performance can be expected. For example, Non-PTL 1 describes that a poly(methylsilsesquioxane)-based SOG material is directly imprinted and then vitrified, whereby an insulation film having a pattern is produced.

PTL 1 describes that room temperature imprinting using organosilica-based SOG and hydrogenated silsesquioxane polymer (HSQ) is adopted.

PTL 2 describes that a fine pattern with a high elastic modulus is formed by optical nanoimprinting using a composition including a mixture of silica nano particles and a photocurable monomer.

### CITATION LIST

### Patent Literature

PTL 1: Japanese Unexamined Patent Application Publication No. 2003-100609
PTL 2: Japanese Unexamined Patent Application Publication No. 2013-86294

### Non Patent Literature

Non-PTL 1: Adv. Mater. 2007, 19, 2919-2924

### SUMMARY OF INVENTION

### Technical Problem

However, in the technology described in Non-PTL 1, pattern formation by heat imprinting that uses a high viscosity SOG material is adopted, and accordingly an imprinting press process needs to be performed at a high temperature (200° C.) and a high pressure (3.4 MPa) under vacuum, so that temperature rise and temperature drop take a long time. Accordingly it is very difficult to increase throughput.

The technology described in PTL 1 needs a press process at a high pressure (25 kgf/cm²) for a long time (10 minutes), and accordingly the effect of increasing throughput is limited. Furthermore, due to stability after application, pressing to be performed within 10 minutes after the application, and therefore the technology cannot be applied to a process with long-cycle time.

The application of the technology described in PTL 2 is limited to replica molding applications because the silica nano particles include a component having a large particle diameter of several hundred nm and aggregated secondary particles, and therefore the silica nano particles are not uniformly filled in the fine pattern of a mold.

As described above, the development of a coating composition for producing an interlayer insulation film and a method for producing an interlayer insulation film has been demanded, in which the coating composition makes it possible to produce an interlayer insulation film patterned and having a high Young’s modulus and a low relative dielectric constant in high throughput.

An object of the present invention is to provide a coating composition for producing an interlayer insulation film, the coating composition making it possible to produce an interlayer insulation film patterned and having a high Young’s modulus and a low relative dielectric constant in high throughput.

Another object of the present invention is to provide an interlayer insulation film patterned and having a high Young’s modulus and a low relative dielectric constant.

Another object of the present invention is to provide a semiconductor element including an interlayer insulation film patterned and having a high Young’s modulus and a low relative dielectric constant.

Another object of the present invention is to provide a method for producing an interlayer insulation film, the method being capable of producing an interlayer insulation film patterned and having a high Young’s modulus and a low relative dielectric constant in high throughput.

### Solution to Problem

The inventors of the present invention conducted extensive studies to achieve the above-mentioned objects. As a result, the inventors found that, through the use of a coating composition for producing an interlayer insulation film, the coating composition including a polymerizable compound having a specific group, an interlayer insulation film patterned and having a high Young’s modulus and a low relative dielectric constant can be produced in high throughput, and the inventors accomplished the present invention.

That is, the present invention provides a coating composition for producing an interlayer insulation film, the coating composition including a polymerizable compound (A) and a photopolymerization initiator (B), in which the polymerizable compound (A) is a polymerizable silicon compound having two or more polymerizable groups, and at least one of the two or more polymerizable groups is a polymerizable group Q expressed by the following formula (1) .

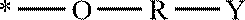

(In the formula (1),
* represents a bond with a silicon atom,
R represents a single bond or an unsubstituted or substituted alkylene group having 1 to 12 carbon atoms and optionally containing a heteroatom, and
Y represents a polymerizable group.)

Furthermore, the present invention provides an interlayer insulation film obtained by curing the coating composition for producing the interlayer insulation film.

Furthermore, the present invention provides a semiconductor element including the above-mentioned interlayer insulation film.

Furthermore, the present invention provides a method for producing an interlayer insulation film, the method including: a step A of applying the coating composition for producing the interlayer insulation film onto a substrate; a step B of pressing an imprinting mold patterned with projections and depressions against a surface of the coating composition for producing the interlayer insulation film; a step C of photo-curing the coating composition for producing the interlayer insulation film; a step D of removing the imprinting mold; and a step E of baking the coating composition for producing the interlayer insulation film at 200° C. or higher to form the interlayer insulation film.

### Advantageous Effects of Invention

According to the present invention, there can be provided a coating composition for producing an interlayer insulation film, the coating composition making it possible to produce the interlayer insulation film in high throughput, the interlayer insulation film being patterned and having a high Young’s modulus and a low relative dielectric constant.

According to the present invention, there can be provided an interlayer insulation film patterned and having a high Young’s modulus and a low relative dielectric constant.

According to the present invention, there can be provided a semiconductor element including an interlayer insulation film patterned and having a high Young’s modulus and a low relative dielectric constant.

According to the present invention, there can be provided a method for producing an interlayer insulation film in high throughput, the interlayer insulation film being patterned and having a high Young’s modulus and a low relative dielectric constant.

### DESCRIPTION OF EMBODIMENTS

In one embodiment according to the present invention, a coating composition for producing an interlayer insulation film (hereinafter, sometimes simply referred to as “the coating composition”) includes a polymerizable compound (A) and a photopolymerization initiator (B), in which the polymerizable compound (A) is a polymerizable silicon compound having two or more polymerizable groups, and at least one of the two or more polymerizable groups is a polymerizable group Q expressed by the following formula (1) .

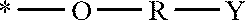

(In the formula (1),
* represents a bond with a silicon atom,
R represents a single bond or an unsubstituted or substituted alkylene group having 1 to 12 carbon atoms and optionally containing a heteroatom, and
Y represents a polymerizable group.)

The polymerizable group Q is directly chemically bonded to a silicon atom, and accordingly a cured film obtained by curing the coating composition is excellent in uniformity, unlike the case of using a composition including a mixture of silica nano particles and a photocurable monomer. Furthermore, the polymerizable group Q has a Si-O-R bond site, hence, a substrate is heated after pattern formation to cause vitrification, whereby an interlayer insulation film having a high Young’s modulus and a low dielectric constant can be obtained. Furthermore, in the polymerizable group Q, the Si-O-R bond site can be decomposed by treatment with acid, alkali, or the like to cut a cross-linking structure, whereby the photo-cured product can be intentionally dissolved and washed. Therefore, when a defect is produced in pattern formation during photo-imprinting or when contamination due to the photo-cured product remains on a mold, the defect and the contamination can be easily removed by washing. Furthermore, the Si-O-R bond site of the polymerizable group Q is heat-decomposable. Accordingly, the Si-O-R bond site is decomposed by heating a substrate after pattern formation and a void is formed in the interlayer insulation film, so that the interlayer insulation film can have a low dielectric constant. Furthermore, the coating composition has low viscosity and is photocurable, hence, without vacuum processing such as chemical vapor deposition (CVD), the coating composition can be applied onto a substrate at room temperature and atmospheric pressure, and photocured. Therefore, an interlayer insulation film can be formed in higher throughput than in conventional cases. Thus, through the use of the coating composition, an interlayer insulation film patterned, being excellent in uniformity, and having a high Young’s modulus and a low relative dielectric constant can be produced in high throughput. Furthermore, the coating composition is cured at a low shrinkage, hence an interlayer insulation film obtained by curing the coating composition is excellent in crack resistance and flatness. Furthermore, the coating composition can be preferably used for the formation of a pattern particularly with a size of 100 nm or smaller.

The polymerizable compound (A) is a liquid at room temperature (for example, 25° C.) and has two or more polymerizable groups. The polymerizable group is a functional group capable of undergoing a polymerization reaction, specifically a radical polymerizable group or a cationic polymerizable group, and preferably a radical polymerizable group. Specific examples of the radical polymerizable group include a vinyl group, a (meth)acryloyl group, a (meth)acryloyloxy group, an allyl group, an allyloxy group, an isopropenyl group, a styryl group, a vinyloxy group, a vinyloxycarbonyl group, a vinyl carbonyl group, a N-vinylamino group, a methacrylamide group, an acrylamide group, and a maleimide group. From the viewpoint of photocurability, a (meth)acryloyl group and an acrylamide group are preferable, and an acryloyl group is particularly preferable. A group having the polymerizable group is beneficially a group having any of the polymerizable groups. Note that, in the present specification, a (meth)acryloyl group is an acryloyl group or a methacryloyl group.

The polymerizable compound (A) has two or more polymerizable groups, and at least one of groups having the above-mentioned polymerizable groups is the polymerizable group Q expressed by the formula (1).

The polymerizable compound (A) has at least one group Q. When the polymerizable compound (A) has three or more groups Q, a cured product having excellent photocurability and a high elastic modulus can be achieved. The polymerizable compound (A) having three or more polymerizable groups Q is preferable because the polymerizable compound (A) is not only curable at a low luminous intensity in a short time, but also capable of preventing pattern collapse and pattern breakage at the step of removing a mold during photo-imprinting, and furthermore enhancing ease of washing and insulation properties.

In the polymerizable group Q expressed by the formula (1), R is preferably a single bond or an alkylene group having 1 to 5 carbon atoms.

In the polymerizable group Q expressed by the formula (1), Y is preferably a vinyl group, a (meth)acryloyl group, a (meth)acryloyloxy group, an allyl group, an allyloxy group, an isopropenyl group, a styryl group, a vinyloxy group, a vinyloxycarbonyl group, a vinyl carbonyl group, a N-vinylamino group, an acrylamide group, a methacrylamide group, or a maleimide group.

Examples of the polymerizable group Q include a polymerizable group having the following structure.

[Chem. 1]

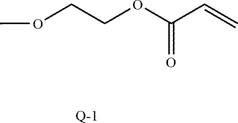

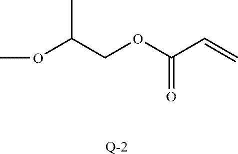

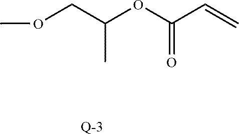

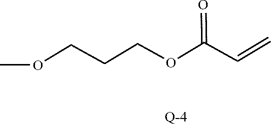

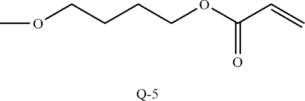

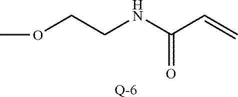

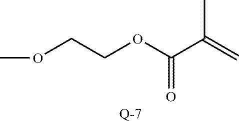

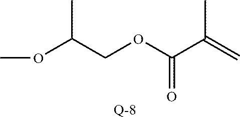

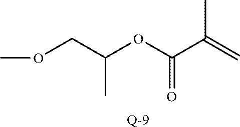

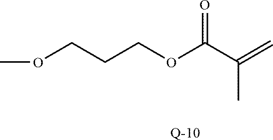

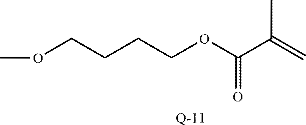

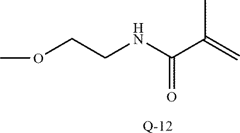

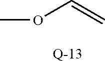

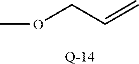

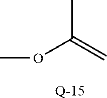

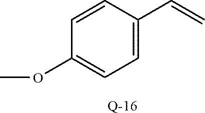

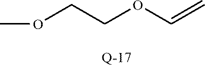

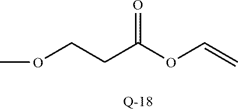

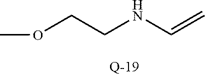

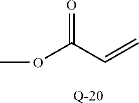

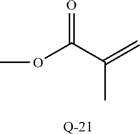

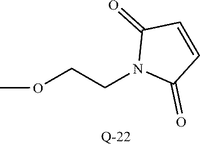

The polymerizable compound (A) may have a linear chain structure or a branched chain structure.

Examples of the polymerizable compound (A) include the polymerizable compounds having the following structures in which 2 to 6 silicon atoms are contained in a molecule and 1 to 4 oxygen atoms are directly bonded to a silicon atom.

The number of the silicon atoms and the number of the oxygen atoms are not limited to the exemplified numbers.

The number of the silicon atoms that the polymerizable silicon compound (A) has in a molecule is 2 to 5000, for example, meanwhile the number of the oxygen atoms directly bonded to the silicon atoms can be selected in a range of 1 to 4.

[Chem. 2]

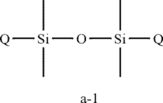

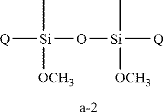

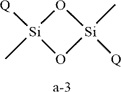

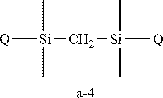

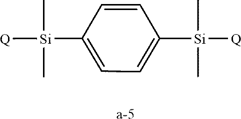

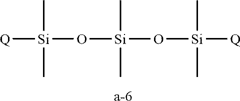

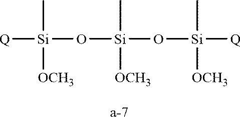

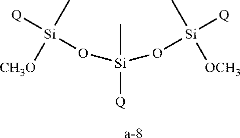

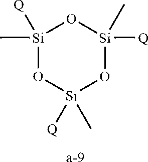

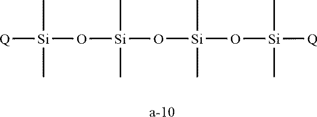

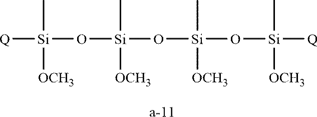

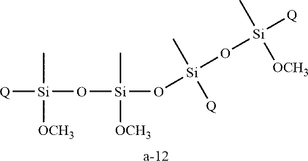

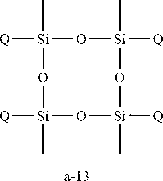

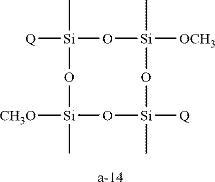

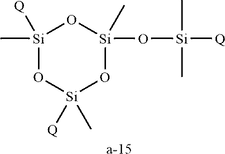

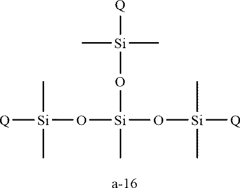

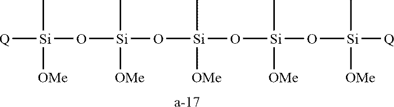

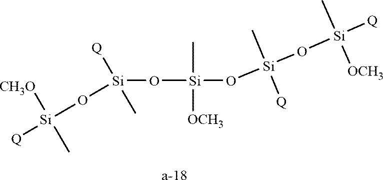

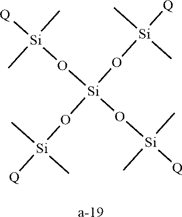

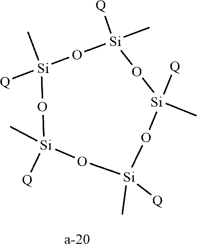

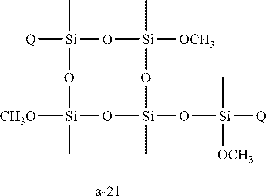

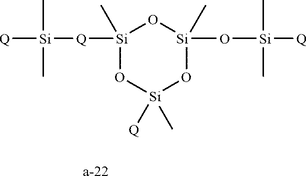

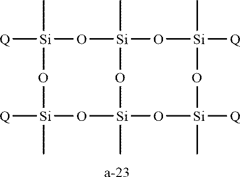

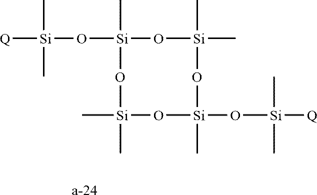

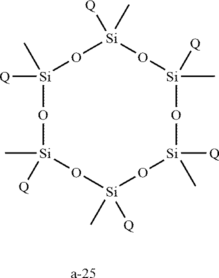

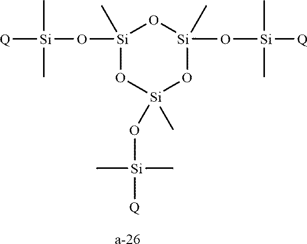

Among the above-mentioned structures, the polymerizable compound (A) preferably has a structure having 5 or more silicon atoms.

This is because the presence of 5 or more silicon atoms leads to improvement of crack resistance in production of the interlayer insulation film and improvement of heat resistance, insulation properties, and Young’s modulus of the formed insulation film.

The amount of silicon atoms in the polymerizable compound (A) is preferably 10% by weight or more. The reason why the amount of silicon atoms is preferably 10% by weight or more is that outgassing components generated by disconnection from a surface of a sample surface is reduced and heat resistance and crack resistance are enhanced.

The amount of silicon atoms in the polymerizable compound (A) is preferably 15% by weight or more, and more preferably 20% by weight or more.

The upper limit of the amount of silicon atoms in the polymerizable compound (A) is not particularly limited, but is, for example, 90% by weight or less, preferably 80% by weight or less, more preferably 70% by weight or less, and still more preferably 60% by weight or less.

The polymerizable compound (A) is preferably produced by condensing a monomer expressed by the following formula (A1) and/or a monomer expressed by the following formula (A2) to obtain a silicone oligomer and reacting the obtained silicone oligomer with a compound expressed by the following formula (A3). [0037]

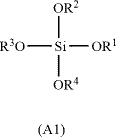

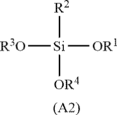

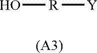

(In the formulae (A1), (A2), and (A3),
R¹, R², R³, and R⁴ each independently represent an alkyl group having 1 to 6 carbon atoms,
R is the same as R in the formula (1), and
Y is the same as Y in the formula (1).)

The polymerizable compound (A) obtained by reacting the silicone oligomer of the monomer expressed by the formula (A1) and/or the monomer expressed by the formula (A2) with the compound expressed by the formula (A3) is a silicone oligomer having at least one group expressed as Si-O-R-Y.

Since the silicone oligomer has a group expressed as Si-O-R-Y, a composition having low viscosity and excellent UV-curability can be achieved. Furthermore, when a composition including the silicone oligomer is baked at high temperature to form an interlayer insulation film, the group expressed as Si-O-R-Y is decomposed to form a siloxane bond, whereby the interlayer insulation film can be made stronger.

Commercially available products of the silicone oligomer of the monomer expressed by the formula (A1) and/or the monomer by the formula (A2) can be used. Examples of the commercially available silicone oligomer include silicone resin KC-89S, silicone resin KR-500, silicone resin X-40-9225, silicone resin KR-401N, silicone resin X-40-9227, silicone resin KR-510, silicone resin KR-9218, and silicone resin KR-213 (manufactured by Shin-Etsu Chemical Co., Ltd.), and ethyl silicate 40, ethyl silicate 48, methyl silicate 51, methyl silicate 53A, and EMS-485 (manufactured by COLCOAT CO., LTD.).

The lower limit of the amount of the polymerizable compound (A) contained in the coating composition is preferably 50% by weight or more, 60% by weight or more, 70% by weight or more, or 80% by weight or more with respect to the non-volatile content of the coating composition.

The upper limit of the amount of the polymerizable compound (A) contained in the coating composition is not particularly limited, and is, for example, 99.9% by weight or less, 99% by weight or less, or 95% by weight or less with respect to the non-volatile content of the coating composition.

The weight-average molecular weight of the polymerizable compound (A) is in a range from preferably 500 or more, and more preferably 1,000 or more, to preferably 100,000 or less, and more preferably 10,000 or less. The weight-average molecular weight is preferably 500 or more because such weight-average molecular weight leads to improvement of crack resistance during production of an interlayer insulation film and improvement of heat resistance, insulation properties, and Young’s modulus of the formed insulation film. The weight-average molecular weight is preferably 100,000 or less because such weight-average molecular weight causes the viscosity to be kept low at room temperature and leads to excellence in filling properties into a mold during photo-imprinting. Note that, in the present specification, the weight-average molecular weight is measured by a method described in Examples.

A method for synthesis of the polymerizable compound (A) is not particularly limited, and a known and commonly used method can be adopted. Examples of the method for the synthesis of the polymerizable compound (A) include: a method of performing synthesis with chlorosilane through a dehydrochlorination reaction by using a compound having a polymerizable unsaturated group and a hydroxy group as a raw material; and a method of performing synthesis with alkoxy silane through ester interchange.

Specific examples of the photopolymerization initiator (B) include 2,2-dimethoxy-1,2-diphenylethan-1-one, 1-hydroxy-cyclohexyl-phenyl-ketone, 1-[4-(2-hydroxyethoxy)-phenyl]-2-hydroxy-2-methyl-1-propan-1-one, 2-methyl-1-[4-(methylthio)phenyl]-2-morpholinopropan-1-one, 2-benzyl-2-dimethylamino-1-(4-morpholinophenyl)-butanone-1, bis(2,4,6-trimethylbenzoyl)-phenylphosphine oxide, 2-hydroxy-1-{4-[4 -(2-hydroxy-2-methyl-propionyl)-benzyl]-phenyl}-2-methylpropane, 1,2-octanedione 1-[4-(phenylthio)- 2-(O-benzoyloxime)], 2-hydroxy-2-methyl-1-phenyl-propane-1-one, phenylglyoxylic acid methyl ester, and 2,4,6-trimethylbenzoyl-diphenyl-phosphine oxide. As long as the photopolymerization initiator (B) absorbs photons of a light source used for photo-curing, the photopolymerization initiator (B) is not limited to a particular one. The above-mentioned photopolymerization initiators may be used alone or in combination of two or more.

The photopolymerization initiator (B) is commercially available, and examples of the commercially available photopolymerization initiator (B) include: OMNIRAD (registered trademark) 651, 184, 2959, 907, 369, 379, 819, 127, and ESACURE (registered trademark) KIP150, TZT, KTO46, 1001M, KB1, KS300, KL200, TPO, ITX, and EDB (each manufactured by IGM Resins); and Irgacure (registered trademark) OXE01 and 02, and DAROCUR (registered trademark) 1173, MBF, and TPO (each manufactured by BASF Japan Ltd.).

The amount of the photopolymerization initiator (B) contained in the coating composition is in a range from preferably 0.5 part by weight or more, and more preferably 1 part by weight or more, to preferably 20 parts by weight or less, and more preferably 10 parts by weight or less, with respect to 100 parts by weight of the total of the polymerizable compound (A) and a polymerizable compound (described below) other than the polymerizable compound (A). When the amount of the photopolymerization initiator (B) contained in the coating composition is 0.5 part by weight or more with respect to 100 parts by weight of the polymerizable compound (A) and the polymerizable compound other than the polymerizable compound (A), curability increases and pattern formability is excellent.

The coating composition may contain other components within a range where the effect of the present invention is not impaired. Examples of the other components include a solvent, a mold release agent, a pore-forming agent, a polymerizable monomer other than the polymerizable compound (A), an organic pigment, an inorganic pigment, an extender pigment, an organic filler, an inorganic filler, a photosensitizer, an ultraviolet absorbent, an antioxidant, and an adhesion aid.

The solvent, if contained in the coating composition, can improve film thickness and surface smoothness when the coating composition is applied using spin-coating, for example. Examples of the solvent include aliphatic or alicyclic hydrocarbons, such as n-hexane, n-heptane, n-octane, cyclohexane, and cyclopentane; aromatic hydrocarbons, such as toluene, xylene, ethyl benzene, and anisole; alcohols, such as methanol, ethanol, n-butanol, ethylene glycol monomethyl ether, propylene glycol monomethyl ether, propylene glycol monoethyl ether, and methyl isobutyl carbinol; esters, such as ethyl acetate, n-butyl acetate, isobutyl acetate, ethylene glycol monomethyl ether acetate, and propylene glycol monomethyl ether acetate; ketones, such as acetone, methyl ethyl ketone, methyl isobutyl ketone, and cyclohexanone; alkyl ethers; ethers, such as 1,2-dimethoxyethane, tetrahydrofuran, and dioxane; lactones, such as γ-butyrolactone; N-methylpyrrolidone; dimethylformamide; and dimethylacetamide. These solvents can be used alone or in combination of two or more.

The solvent can be used in an amount such that the amount of components other than the solvent that are contained in the coating composition is preferably in a range from 0.1% by weight or more to less than 100% by weight.

When the coating composition is hard to release from a mold during photo-imprinting, the mold release agent, if contained, can reduce a force required to remove the mold, and thereby prevent the collapse, deformation, and breakage of a pattern. The mold release agent is preferably segregated at an interface with the mold in the coating composition and preferably has the function of promoting the release of the coating composition from the mold. Specific examples of the mold release agent include a compound having both a functional group having a high affinity for a surface of the mold and a hydrophobic functional group in one molecule. Examples of the functional group having a high affinity for the surface of the mold include a hydroxy group, an ether group, an amide group, an imide group, a ureido group, a urethane group, a cyano group, a sulfonamide group, a lactone group, a lactam group, a cyclocarbonate group, and a phosphate group. For example, when the mold is made of quartz, a hydroxy group, a polyalkylene glycol group obtained by etherifying a hydroxy group, or the like is preferable, meanwhile, when the mold is made of metal such as nickel, a phosphate group or the like is preferable. Examples of the hydrophobic functional group include a functional group selected from, for example, a hydrocarbon group and a fluorine-containing group. Examples of the mold release agent include a polyoxyalkylene alkyl ether-based surfactant, a polyoxyalkylene fatty acid ester-based surfactant, a sorbitan fatty acid ester-based surfactant, a polyoxyalkylene alkylamine-based surfactant, a fluorosurfactant, and an acrylic polymerization-based surfactant. The mold release agent is commercially available. Examples of the polyoxyalkylene alkyl ether-based surfactant include NONION K-204, K-220, K-230, P-208, P-210, P-213, E-202, E-205, E-212, E-215, E-230, S-202, S-207, S-215, S-220, and B-220 (each manufactured by NOF CORPORATION). Examples of the fluorosurfactant include Fluorad FC-4430 and FC-4431 (each manufactured by Sumitomo 3M), SURFLON S-241, S-242, and S-243 (each manufactured by AGC Inc.), F-top EF-PN31M-03, EF-PN31M-04, EF-PN31M-05, EF-PN31M-06, and MF-100 (each manufactured by Mitsubishi Materials Electronic Chemicals Co., Ltd.), Polyfox PF-636, PF-6320, PF-656, and PF-6520 (each manufactured by OMNOVA Solutions Inc.), FTERGENT 250, 251, 222F, and 212M DFX-18 (each manufactured by NEOS COMPANY LIMITED), UNIDYNE DS-401, DS-403, DS-406, DS-451, and DSN-403N (each manufactured by DAIKIN INDUSTRIES, LTD.), MEGAFACE F-430, F-444, F-477, F-553, F-556, F-557, F-559, F-562, F-565, F-567, F-569, and R-40 (each manufactured by DIC Corporation), and Capstone FS-3100, Zonyl FSO-100 (each manufactured by DuPont de Nemours, Inc). The above-mentioned mold release agents can be used alone or in combination of two or more. The coating composition preferably contains the mold release agent because the imprinting mold can be more easily removed from the coating composition.

The amount of the mold release agent contained in the coating composition is in a range from preferably 0.1% by weight or more, and more preferably 0.2% by weight or more, to preferably 10% by weight or less, and more preferably 5% by weight or less. The amount of the mold release agent contained in the coating composition is preferably 0.1% by weight or more for the purpose of enhancing releasability.

The pore-forming agent is not particularly limited as long as the pore-forming agent is capable of forming an interlayer insulation film having a desired pore amount and a desired pore diameter, for example, and can be mixed with the coating composition, but the pore-forming agent is preferably a surfactant having a polyalkylene glycol structure from the viewpoint of pore formability. In particular, a Pluronic-based surfactant (a triblock copolymer of polyethylene oxide and polypropylene oxide) and a Tetronic-based surfactant (a tetrafunctional block copolymer derived by successively adding propylene oxide and ethylene oxide to ethylene diamine) are more preferable from the viewpoint of solubility in the coating composition. The molecular weight of the surfactant used for the pore-forming agent and having a polyalkylene glycol structure is in a range from preferably 200 or more, and more preferably 500 or more, to preferably 20,000 or less, and more preferably 10,000 or less. When the molecular weight is 200 or more, a pore having a sufficient diameter can be formed, meanwhile, the molecular weight is preferably 20,000 or less because the surfactant is excellent in solubility in the coating composition. The pore-forming agent is commercially available. Examples of the commercially available pore-forming agent include EPAN 410, 420, 450, 485, 680, 710, 720, 740, 750, 785, U-103, U-105, and U-108 (each manufactured by DKS Co. Ltd.), and Tetronic (registered trademark) 304, 901, 904, 908, 1107, 1301, 137, and 150R1 (each manufactured by BASF SE). The above-mentioned pore-forming agents can be used alone or in a combination of two or more. The coating composition preferably contains the pore-forming agent because more pores can be formed in the interlayer insulation film, so that the relative dielectric constant of the interlayer insulation film decreases and the insulation properties of the interlayer insulation film can be further enhanced.

The amount of the pore-forming agent contained in the coating composition can be suitably selected in accordance with the amount of pores formed in the targeted interlayer insulation film. The amount of the pore-forming agent contained in the coating composition is in a range from preferably 0.1% by weight or more, and more preferably 0.5% by weight or more with respect to the non-volatile content of the coating composition, to preferably 20% by weight or less, more preferably 10% by weight or less with respect to the non-volatile content of the coating composition. The amount of the pore-forming agent contained in the coating composition is preferably 0.1% by weight or more because an interlayer insulation film having a further lower relative dielectric constant and further higher insulating properties can be produced, meanwhile the amount of the pore-forming agent contained in the coating composition is preferably 20% by weight or less because excellent crack resistance can be achieved.

Examples of the polymerizable monomer other than the polymerizable compound (A) include a monofunctional polymerizable monomer and a polyfunctional polymerizable monomer.

The monofunctional polymerizable monomer is a compound having one polymerizable group. The polymerizable group denotes a functional group capable of polymerization reaction. Specific examples of the polymerizable group include a radical polymerizable group and a cationic polymerizable group. The polymerizable group of the monofunctional polymerizable monomer is preferably a group capable of reacting with the polymerizable group of the polymerizable compound (A). For example, when the polymerizable group of the polymerizable compound (A) is a (meth)acryloyl group, the polymerizable group of the monofunctional polymerizable monomer is also preferably a (meth)acryloyl group.

Specific examples of the monofunctional polymerizable monomer include hydroxyethyl (meth)acrylate, hydroxypropyl (meth)acrylate, hydroxybutyl (meth)acrylate, polyethylene glycol mono(meth)acrylate, polypropylene glycol mono(meth)acrylate, benzyl (meth)acrylate, phenylbenzyl (meth)acrylate, phenoxybenzyl (meth)acrylate, phenol EO-modified (meth)acrylate, o-phenylphenol EO-modified (meth)acrylate, p-cumylphenol EO-modified (meth)acrylate, nonylphenol EO-modified (meth)acrylate, monohydroxyethyl phthalate (meth)acrylate, 2-hydroxy-3-phenoxypropyl (meth)acrylate, 2-(phenylthio)ethyl (meth)acrylate, cyclohexyl (meth)acrylate, tetrahydrofurfuryl (meth)acrylate, dicyclopentenyl (meth)acrylate, dicyclopentenyloxyethyl (meth)acrylate, dicyclopentanyl (meth)acrylate, isoboronyl (meth)acrylate, and adamantyl (meth)acrylate. The monofunctional polymerizable monomer is particularly preferably a silicon-containing monomer. This is because, when the monomer contains silicon, dry etching resistance of a curable composition containing the monofunctional polymerizable monomer is enhanced. Specific examples of the silicon-containing monomer include vinyltrimethoxysilane, vinyltriethoxysilane, vinylmethyldimethoxysilane, vinyltri(2-methoxy ethoxy)silane, vinyltriacetoxysilane, 2-trimethoxysilyl ethyl vinyl ether, 3-(meth)acryloyloxypropyltrimethoxysilane, 3-(meth)acryloyloxypropyltriethoxysilane, 3-(meth)acryloyloxypropylmethyldimethoxysilane, styryltrimethoxysilane, and one-end reactive silicone oil (X-22-174ASX, X-22-174BX, KF-2012, X-22-2426, and X-22-2475, manufactured by Shin-Etsu Chemical Co., Ltd.). In the present specification, (meth)acrylate denotes acrylate or methacrylate.

The amount of the monofunctional polymerizable monomer contained in the coating composition is in a range of preferably 30% by weight or less, and more preferably 10% by weight or less with respect to the non-volatile content of the coating composition.

Specific examples of the polyfunctional polymerizable monomer include 1,2-ethanediol di(meth)acrylate, 1,2-propanediol di(meth)acrylate, 1,4-butanediol di(meth)acrylate, 1,6-hexanediol di(meth)acrylate, dipropylene glycol di(meth)acrylate, neopentyl glycol di(meth)acrylate, tripropylene glycol di(meth)acrylate, trimethylolpropane di(meth)acrylate, trimethylolpropane tri(meth)acrylate, tris(2-(meth)acryloyloxy)isocyanurate, pentaerythritol tri(meth)acrylate, pentaerythritol tetra(meth)acrylate, di(trimethylolpropane) tetra(meth)acrylate, di(pentaerythritol) penta(meth)acrylate, di(pentaerythritol) hexa(meth)acrylate, tricyclodecanedimethanol di(meth)acrylate, ethylene oxide-added bisphenol A di(meth)acrylate, ethylene oxide-added bisphenol F di(meth)acrylate, propylene oxide-added bisphenol A di(meth)acrylate, propylene oxide-added bisphenol F di(meth)acrylate, di(meth)acrylate having a 9,9-bisphenylfluorene skeleton, and (meth)acrylate-modified silicone (for example, X-22-2445, X-22-1602, X-22-164, X-22-164AS, X-22-164A, X-22-164B, X-22-164C, X-22-164E, KR-513, X-40-2672B, and X-40-9272B, manufactured by Shin-Etsu Chemical Co., Ltd.), and (meth)acrylate-modified silsesquioxane (for example, AC-SQ TA-100, MAC-SQ TM-100, AC-SQ SI-20, and MAC-SQ SI-20, manufactured by TOAGOSEI CO., LTD.). The polyfunctional polymerizable monomer is particularly preferably (meth)acrylate-modified silicone (for example, X-22-2445, X-22-1602, X-22-164, X-22-164AS, X-22-164A, X-22-164B, X-22-164C, X-22-164E, KR-513, X-40-2672B, and X-40-9272B, manufactured by Shin-Etsu Chemical Co., Ltd.) and (meth)acrylate-modified silsesquioxane (for example, AC-SQ TA-100, MAC-SQ TM-100, AC-SQ SI-20, and MAC-SQ SI-20, manufactured by TOAGOSEI CO., LTD.).

The amount of the multifunctional polymerizable monomer contained in the coating composition is in a range of preferably 30% by weight or less, and more preferably 10% by weight or less with respect to the non-volatile content of the coating composition.

In the coating composition, the amount of silicon atoms in the non-volatile content is preferably 10% by weight or more. The reason why the amount of silicon atoms in the non-volatile content is preferably 10% by weight or more is that the amount of outgas components released and generated from a sample surface is reduced and heat resistance and crack resistance are enhanced. The amount of silicon atoms in the non-volatile content is preferably 15% by weight or more, and more preferably 20% by weight or more.

The total amount of the polymerizable compound (A) and the polymerizable monomer other than the polymerizable compound (A) in the non-volatile content of the coating composition is preferably 50% by weight or more. This is because an increase in the number of three-dimensional cross-linking points leads to excellent pattern formability during imprinting.

The interlayer insulation film according to the present embodiment is obtained by curing the coating composition. The interlayer insulation film according to the present embodiment has a high Young’s modulus and a low relative dielectric constant. The interlayer insulation film may be subjected to pattern formation. The pattern formation may be performed by nanoimprinting.

The interlayer insulation film can be produced by a method for producing the interlayer insulation film, the method including: a step A of applying the coating composition onto a substrate; a step B of pressing an imprinting mold patterned with projections and depressions against a surface of the coating composition for producing the interlayer insulation film; a step C of photo-curing the coating composition for producing the interlayer insulation film; a step D of removing the imprinting mold; and a step E of baking the coating composition for producing the interlayer insulation film at 200° C. or higher to form the interlayer insulation film. According to the method for producing the interlayer insulation film, an interlayer insulation film patterned and having a high Young’s modulus and a low relative dielectric constant can be produced in high throughput.

There is no particular limitation on a method for applying the coating composition onto the substrate at the step A. Various methods, such as spraying, spin coating, dipping, roll coating, blade coating, a doctor roll method, a doctor blade method, curtain coating, slit coating, screen printing, and inkjet printing, are beneficially used. Among these methods, spin coating is preferably used from the viewpoints of film thickness adjustment, surface smoothness, in-plane film thickness uniformity, and throughput.

The substrate can be selected in accordance with various applications. Examples of the substrate include quartz, sapphire, glass, plastics, ceramic materials, vapor deposition films (for CVD, PVD, and sputtering), magnetic films, reflective films, metal substrates of Ni, Cu, Cr, Fe, stainless steel, and the like, paper, Spin On Glass (SOG), Spin On Carbon (SOC), polymer substrates, such as a polyester film, a polycarbonate film, and a polyimide film, TFT array substrates, electrode plates of PDP, conductive substrates, such as ITO and metal, insulating substrates, substrates for semiconductor preparation, such as silicon, silicon nitride, polysilicon, silicon oxide, and amorphous silicon.

Furthermore, the shape of the substrate is not particularly limited, and may be any shape that meets a purpose, such as a flat shape, a sheet shape, or a three-dimensional shape having a curvature over the entirety or part of a surface thereof. Furthermore, the hardness, thickness, and the like of the substrate are not particularly limited.

At the step B, the imprinting mold patterned in advance with projections and depressions is pressed against a surface of the coating composition on the substrate.

Examples of a material for the imprinting mold include: optically transparent materials, such as quartz, ultraviolet ray transmitting glass, sapphire, diamond, a silicone material such as polydimethylsiloxane, a fluoro-resin, a cycloolefin resin; and other resin materials that are optically transparent. Furthermore, when the substrate to be used is an optically transparent material, the imprinting mold may be a material not allowing light transmission. Examples of the optically non-transparent material include metal, SiC, and mica. Among these materials, a quartz mold is particularly preferable because the quartz mold provides good ultraviolet ray transmission and has high hardness, surface flatness, thickness uniformity, and parallelism. The shape of the imprinting mold can be any shape selected from a flat shape, a belt shape, a roll shape, and a roll belt shape.

The imprinting mold may be a mold having undergone mold release treatment to improve releasability of the coating composition from a surface of the mold. Examples of the mold release treatment include treatment with a silicone-based or fluorine-based silane coupling agent.

Note that, when the coating composition contains a solvent, the method for producing the interlayer insulation film may further include a step F of, prior to the step B, prebaking the coating composition on the substrate in order to remove the solvent from the coating composition. At the step F, temperature for the prebaking can be suitably determined, for example, from 50° C. or higher, and preferably 70° C. or higher, to 150° C. or lower, and preferably 120° C. or lower.

Examples of a method for curing the coating composition at the step C include a method of irradiation with light from the mold side when the mold is made of an optically transparent material and a method of light irradiation from the substrate side when the substrate is made of an optically transparent material. Light used for the light irradiation is beneficially light to which the photopolymerization initiator (B) reacts. Particularly, light having a wavelength of 450 nm or less (active energy rays, such as ultraviolet rays, X-rays, and γ-rays) is preferable because the photopolymerization initiator (B) easily reacts by the light and curing can be performed at a lower temperature.

When there is a problem in traceability of a pattern to be formed, the coating composition may be heated to a temperature at which sufficient fluidity can be obtained during light irradiation. The temperature for the heating is preferably 100° C. or lower, and more preferably 80° C. or lower. By heating at the above-mentioned temperature, the shape of a pattern formed from the coating composition is retained with high accuracy.

At the step D, the mold is removed, whereby the coating composition patterned with projections and depressions to which projections and depressions of the mold are transferred is obtained. In order to suppress deformation such as warpage of the substrate or to increase the accuracy of the pattern with projections and depressions, the step D is preferably performed after the temperature of the coating composition decreases to approximately room temperature (25° C.) .

After the removal of the mold, if a resist residue is observed on the mold, washing of the mold is performed. Since the mold is used repeatedly, a resist residue remaining on the mold adversely affects pattern formation at the next usage of the mold. The polymerizable compound (A) contained in the coating composition has the group Q. The group Q is a hydrolyzable group, and therefore, when hydrolysis treatment is performed after curing, the mold is washed satisfactorily. Examples of a hydrolyzable washing liquid used for washing of the mold include acids, alkalis, and hot water. Examples of an acid washing liquid include sulfuric acid, hydrochloric acid, nitric acid, carbonic acid, acetic acid, phosphoric acid, aqua regia, dilute hydrofluoric acid, a sulfuric acid-hydrogen peroxide mixture, and a hydrochloric acid-hydrogen peroxide mixture. Examples of the alkali washing liquid include not only caustic alkalis, such as caustic soda and caustic potash, and inorganic alkalis, such as various silicates, phosphates, and carbonates, but also organic alkalis, such as tetramethylammonium hydroxide, ammonia water, ammonia hydrogen water, and an ammonia-hydrogen peroxide mixture. There is a risk that the alkali washing liquid may dissolve SiO₂, and therefore, when the mold is formed of glass or quartz, the acid washing liquid is preferably used, and a sulfuric acid-hydrogen peroxide mixture is particularly preferably used. In particular, in the case of washing a quartz mold having a fine pattern of 100 nm or less, there is a risk that the dissolution of SiO₂ in the alkali washing liquid impairs the rectangularity of the mold, and therefore, using the acid washing liquid, the mold is washed without any damage in the fine pattern, and thereby can be used repeatedly. A method for the washing is not particularly limited. Examples of the method for the washing include spraying, shower, immersion, heating immersion, ultrasonic immersion, spinning, bubbling, rocking, brushing, steam, and polishing. Spinning is particularly preferably used for preventing re-attachment of washed-off contaminants.

At the step E, the baking temperature can be suitably determined, and is, for example, from 200° C. or higher, and preferably 250° C. or higher, to 1,000° C. or lower, and preferably 900° C. or lower. When the baking temperature is 200° C. or higher, an interlayer insulation film having a high Young’s modulus can be obtained.

### EXAMPLES

Hereinafter, the present invention will be specifically described with reference to Examples, but the present invention is not limited to Examples. Note that, in Examples, “part” and “%” are used to indicate “part by weight” and “% by weight”, respectively, unless otherwise noted.

### Synthesis Examples

### Synthesis Example 1: Synthesis of Polymerizable Compound (A-1)

A methyl-based silicone resin KR-500 (trade name, manufactured by Shin-Etsu Chemical Co., Ltd.) (110.8 parts), 2-hydroxyethyl acrylate (58.1 parts), and paratoluenesulfonic acid monohydrate (0.034 part) were mixed, and heated to a temperature of 120° C., and allowed to react with stirring for 3 hours while methanol produced by a condensation reaction was distilled off, whereby 152.9 g of a polymerizable compound (A-1) was obtained. The obtained compound had the following physical properties, hence it was confirmed that the compound was a polymerizable compound containing silicon atoms in a molecule. ¹H-NMR (300 MHz, CDC1₃) δ (ppm): 6.43 (m, CH═C), 6.13 (m, C═CH—C═O), 5.83 (m, CH═C), 4.25 (br, CH₂—O—C═O), 3.96 (br, CH₂-O-Si), 3.50 (s, Si-OCH₃), 0.15 (s, Si-CH₃). The weight-average molecular weight measured was 2,510.

### Synthesis Example 2: Synthesis of Polymerizable Compound (A-2)

In the same manner as in Synthesis Example 1, 151.4 g of a polymerizable compound (A-2) was obtained, except that N-(2-hydroxyethyl)acrylamide (58.1 parts) was used in place of 2-hydroxyethyl acrylate (58.1 parts). The obtained compound had the following physical properties, hence it was confirmed that the compound was a polymerizable compound containing silicon atoms in a molecule. ¹H-NMR (300 MHz, CDCl₃) δ (ppm): 7.31 (s, NH), 6.27 to 6.30 (m, C═CH—N), 6.16 to 6.21 (m, CH═C), 5.50 to 5.69 (m, CH═C), 3.32 to 3.98 (m, CH₂-O-Si, N-CH₂), 3.50 (br, Si-OCH₃) , 0.15 (s, Si-CH₃) . The weight-average molecular weight measured was 2,680.

### Synthesis Example 3: Synthesis of Polymerizable Compound (A-3)

In the same manner as in Synthesis Example 1, 152.0 g of a polymerizable compound (A-3) was obtained, except that N-(2-hydroxyethyl)maleimide (58.1 parts) was used in place of 2-hydroxyethyl acrylate (58.1 parts). The obtained compound had the following physical properties, hence it was confirmed that the compound was a polymerizable compound containing silicon atoms in a molecule. ¹H-NMR (300 MHz, CDC1₃) δ (ppm): 6.80 (s, CH═CH), 3.75 to 3.86 (m, CH2-O-Si, N-CH₂), 3.50 (s, Si-OCH₃), 0.15 (s, Si-CH₃). The weight-average molecular weight measured was 2,610.

### Synthesis Example 4: Synthesis of Polymerizable Compound (A-4)

In the same manner as in Synthesis Example 1, 150.0 g of a polymerizable compound (A-4) was obtained, except that methyl silicate (MS-53A, manufactured by COLCOAT CO., LTD.) (110.8 parts) was used in place of the methyl-based silicone resin (KR-500, manufactured by Shin-Etsu Chemical Co., Ltd.) (110.8 parts). The obtained compound had the following physical properties, hence it was confirmed that the compound was a polymerizable compound containing silicon atoms in a molecule. ¹H-NMR (300 MHz, CDC1₃) δ (ppm) : 6.68 to 6.74 (m, CH═C), 6.26 (br, C═CH—C═O), 5.79 to 5.86 (m, CH═C), 4.28 to 4.36 (m, CH₂—O—C═O), 4.03 to 4.12 (m, CH₂-O-Si), 3.44 (br, Si-OCH₃). The weight-average molecular weight measured was 1,050.

### Comparative Synthesis Example 1: Synthesis of Polymerizable Compound (A′-1)

Using a method described in a section on experiments in Non-PTL 1, polymethylsilsesquioxane (PMSQ) was synthesized by polycondensation of methyltrimethoxysilane, 1,2-bis(triethoxysilyl)ethane, and dimethyldimethoxysilane.

Note that the weight-average molecular weight of each of the polymerizable compounds was measured by the following method.
Measurement device: “HLC-8320 GPC”, manufactured by Tosoh Corporation
Column: 2 columns, “Shodex LF604”, manufactured by Shoko Science Co., Ltd.
Column temperature: 40° C.
Detector: RI (differential refractometer)
Developing solvent: toluene (Synthesis Examples 1 and 4), tetrahydrofuran (Synthesis Examples 2 and 3)
Flow rate: 0.5 mL/min
Sample: a solution diluted to 0.5% by mass in terms of resin solids by using the developing solvent and filtered through a microfilter
Injection amount: 20 µL
Standard samples: the following monodisperse polystyrenes
   “A-500”, manufactured by Tosoh Corporation
   “A-5000”, manufactured by Tosoh Corporation
   “F-4”, manufactured by Tosoh Corporation
   “F-40”, manufactured by Tosoh Corporation
   “F-288”, manufactured by Tosoh Corporation

### Evaluation of Interlayer Insulation Film (Non-Patterned Film)

### Coating Composition for Producing Interlayer Insulation Film

Based on formulation illustrated in the following Table 1, components were blended, and then 2 parts by weight of OMNIRAD369 (manufactured by IGM Resins B.V.) as the photopolymerization initiator (B) and 1 part by weight of Nonion S-202 (polyoxyethylene-stearyl ether, manufactured by NOF CORPORATION) as the mold release agent were mixed with 100 parts by weight in total of the polymerizable compound (A) and the monofunctional polymerizable monomer, and dissolved. Subsequently, using propylene glycol monomethyl ether acetate as a solvent, the resultant solution was diluted to achieve 40% to 60% of active components, and the resultant solution was filtered using a polytetrafluoroethylene (PTFE) filter having a pore diameter of 0.2 µm to prepare coating compositions for producing an interlayer insulation film according to Examples 1 to 6 and Comparative Examples 1 to 5, the coating compositions being used for preparation of a non-patterned film.

Components listed in Table 1 below are as follows.

[Polymerizable Compound]
A-1: Polymerizable Compound (A-1)
A-2: Polymerizable Compound (A-2)
A-3: Polymerizable Compound (A-3)
A-4: Polymerizable Compound (A-4)
A′-1: polymethylsilsesquioxane (PMSQ) synthesized by polycondensation of methyltrimethoxysilane, 1,2-bis(triethoxysilyl)ethane, and dimethyldimethoxysilane, the PMSQ being prepared using the method described in the section on experiments in Non-PTL 1.
A′-2: hydrogenated silsesquioxane polymer (HSQ, FOx-16, manufactured by Dow Corning Corp.)
A′-3: composition obtained by substituting 1,4-butanediol diacrylate for a solvent of surface-modified silica particles (MEK-AC 2101, manufactured by Nissan Chemical Corporation), the composition being prepared using a method in Examples described in Japanese Unexamined Patent Application Publication No. 2013-86294.
A′-4: silicone oligomer having an acryloyl group and a methoxy group (KR-513, manufactured by Shin-Etsu Chemical Co., Ltd.)
A′-5: silicone having acryloyl groups at both ends (X-22-2445, manufactured by Shin-Etsu Chemical Co., Ltd.)

### Monofunctional Polymerizable Monomer

ortho-phenylphenoxyethyl acrylate (MIRAMER M1142, manufactured by Miwon Specialty Chemical Co., Ltd.)

### Pore-Forming Agent

poloxamine compound (tetrafunctional ethylene oxide/propylene oxide block copolymer, Tetronic 150R1, manufactured by BASF SE)

### Evaluation Methods

Using each of the obtained coating compositions for interlayer insulation films, preparation of a non-patterned film, evaluation of a Young’s modulus, evaluation of a relative dielectric constant, evaluation of post-exposure delay stability, evaluation of photo-curability, and evaluation of crack resistance were performed by the following methods.

### Preparation of Substrate With Adhesion Film

A surface of a silicon wafer having a diameter of 6 inch was surface-treated with a UV ozone cleaner (UV-1, manufactured by Samco Co., Ltd.), and then, the silicon wafer was placed in a sealed container purged with nitrogen, and nitrogen gas containing 3-acryloxypropyltrimethoxysilane as an adhesion layer agent was allowed to flow into the sealed container and heat-treated at 150° C. for 1 hour, whereby a substrate with an adhesion film was prepared by gas phase treatment.

### Preparation of Non-Patterned Film

The coating composition for producing the interlayer insulation film was applied onto the above-described substrate with the adhesion film by using a spin coater so as to achieve a thickness of approximately 2 to 3 µm, and then, the substrate was pre-baked at 80° C. for 60 seconds. Subsequently, the substrate was irradiated with collimated light at 100 mJ/cm² (for approximately 4 seconds) under nitrogen atmosphere by using a 1-kW Deep UV lamp having a center wavelength of 365 nm so that the coating composition was photo-cured. After the photo-curing, the substrate was baked on a hot plate at 350° C. for 60 seconds to obtain a non-patterned interlayer insulation film resulting from the curing of the coating composition for producing the interlayer insulation film. The film thickness was measured using an optical interference thickness meter (OPTM-A1, manufactured by Otsuka Electronics Co., Ltd.).

### Evaluation of Young’s Modulus of Interlayer Insulation Film

By a nanoindenter (ENT-2100, manufactured by ELIONIX INC.) equipped with a Berkovich indenter, an indentation test was performed at 100 µN or lower on a surface of the non-patterned film having a thickness of approximately 2 to 3 µm. The Young’s modulus of the film was evaluated from an unloading curve in a load displacement curve on the condition that the indentation depth was 200 nm or less. The evaluation criteria are listed below.
A: Young’s modulus > 5 GPa
B: 3 GPa < Young’s modulus ≤ 5 GPa
C: Young’s modulus ≤ 3 GPa

### Evaluation of Relative Dielectric Constant of Interlayer Insulation Film

Furthermore, the coating composition for producing the interlayer insulation film, the coating composition being used for the preparation of the non-patterned film, was diluted by propylene glycol monomethyl ether acetate as a solvent so as to achieve approximately 10% of active components, and then, using a spin coater, the coating composition for producing the interlayer insulation film was applied onto the above-described substrate with the adhesion film so as to achieve a thickness of approximately 100 to 200 nm. Subsequently, the coating composition for producing the interlayer insulation film was cured in the same way to obtain a non-patterned film having an interlayer insulation film thickness of approximately 100 to 200 nm. The film thickness was measured using an optical interference thickness meter (OPTM-A1, manufactured by Otsuka Electronics Co., Ltd.).

The non-patterned film was used to evaluate a relative dielectric constant at 1 MHz by the C-V method using a mercury probe (CVmap92A, manufactured by THE OYAMA COMPANY, LTD.). The evaluation criteria are listed below.
A: relative dielectric constant < 4.0
B: 4.0 ≤ relative dielectric constant <6.0
C: relative dielectric constant ≥ 6.0

### Evaluation of Post-Exposure Delay Stability of Coating Composition for Producing Interlayer Insulation Film

After pre-baking (before photo-curing) in the preparation of the non-patterned film having an approximately 2 to 3 µm thickness, the film was pre-baked at 80° C. for 60 seconds, and then left at room temperature for 24 hours. Subsequently, a surface of the film was rubbed with a clean swab having long polyester fibers to evaluate post-exposure delay stability. Evaluation criteria are listed below.
A: The film was swabbed up and the surface of the substrate was exposed, hence it was confirmed that the coating composition was kept in a low-viscosity liquid state.
B: The film was swabbed up, but stringy, hence it was confirmed that, although the coating composition was in a liquid state, the viscosity thereof increased.
C: The film was not swabbed up, hence it was confirmed that the coating composition was solidified.

### Evaluation of Photo-Curability of Coating Composition for Producing Interlayer Insulation Film

After photo-curing (before baking at 350° C.) in the preparation of the non-patterned film having an approximately 2 to 3 µm thickness, the surface was swabbed up by using a clean swab having long polyester fibers and moistened with ethanol to evaluate photo-curability. Evaluation criteria are listed below.
A: Any change was not observed at the surface of the film.
B: It was observed that the film partially swelled and was partially dissolved at a swabbed portion.
C: The film was removed, and thereby the surface of the substrate was exposed.

### Evaluation of Crack Resistance of Interlayer Insulation Film

A surface of the non-patterned film having a thickness of approximately 2 to 3 µm was observed using an optical microscope (BX53M, manufactured by Olympus Corporation) to evaluate crack resistance. Evaluation criteria are listed below.
A: Any crack was not observed at the surface of the film.
B: A crack was observed at a part of the film.
C: Any crack was not observed over the entire surface of the film.

### Evaluation of Interlayer Insulation Film (Patterned Film)

### Preparation of Coating Composition for Producing Interlayer Insulation Film

The coating composition for producing the interlayer insulation film, the coating composition being used in the preparation of the non-patterned film having a thickness of approximately 2 to 3 µm, was further diluted by propylene glycol monomethyl ether acetate as a solvent so as to achieve approximately 20% of active components, and was filtered using a nylon filter having a pore diameter of 0.01 µm, whereby the coating composition for producing the interlayer insulation film to be used for the preparation of a patterned film was prepared.

### Evaluation Method

Using the obtained coating composition for producing the interlayer insulation film, a patterned film was prepared, and, using the prepared patterned film, fine pattern formability, fine pattern shrinkage, and ease of washing were evaluated, by the following methods.

### Preparation of Patterned Film

The coating composition for producing the interlayer insulation film was applied onto the substrate with the adhesion film by a spin coater so as to achieve a thickness of approximately 500 nm, and then pre-baked at 80° C. for 60 seconds to remove the solvent. The resultant substrate was set on a bottom stage of an optical nanoimprinting device (NM-0401, manufactured by Meisho-Kiko Co., Ltd.) by vacuum suction. A mold (NIM PH-350, manufactured by NTT Advanced Technology Corporation) made of quartz, having an approximately 350 nm to 10 µm line/space pattern, and having a groove depth of approximately 350 nm was fixed to base glass. Then, the mold was coated all around with a Cr film by sputtering deposition to shield the mold from light, and then set on a top stage of the above-mentioned device. The bottom stage was raised to make the substrate and the mold closer enough to bring the substrate and the mold into contact with each other. Subsequently, pressure was applied thereto to 50 N over 10 seconds, and held for 5 seconds, and then the mold and the substrate were exposed from the back side of the mold to collimated light of a mercury lamp with a peak wavelength of 365 nm at 100 mJ/cm² (for approximately 3 seconds). Then, the bottom stage was lowered to remove the mold. In this case, the time required for one time of optical imprinting was 30 seconds or shorter. Baking was performed on a hot plate at 350° C. for 60 seconds to obtain an interlayer insulation film having a fine pattern on a surface thereof.

### Evaluation of Fine Pattern Formability

In the preparation of the patterned film, the interlayer insulation film having a fine pattern in a surface thereof was observed using a scanning electron microscope (SU3800, manufactured by Hitachi High-Tech Corporation) to evaluate fine pattern formability. Evaluation criteria are listed below.
A: Any defect was not observed in the entirety of the pattern.
B: Defects were observed in a part of the pattern.
C: Defects were observed in the entirety of the pattern.

### Evaluation of Shrinkage

In the preparation of the patterned film, after the photo-imprinting and baking at 350° C., the interlayer insulation film having a fine pattern in the surface thereof was observed using a scanning electron microscope (SU3800, manufactured by Hitachi High-Tech Corporation), the height of the pattern was measured, and ((pattern height after photo-imprinting) - ((pattern height after baking) / (pattern height after photo-imprinting)) was calculated, whereby shrinkage was evaluated. Evaluation criteria are listed below.
A: Shrinkage < 7%
B: 7% ≤ Shrinkage < 13%
C: Shrinkage ≥ 13%

### Evaluation of Ease of Washing

In the preparation of the patterned film, after the photo-imprinting, the substrate was immersed in a sulfuric acid solution for 60 seconds and rinsed with ultrapure water to evaluate ease of washing. Evaluation criteria are listed below.
A: The film including the coating composition for producing the interlayer insulation film was completely removed, and thereby a surface of the substrate was exposed.
B: The film including the coating composition for producing the interlayer insulation film was partially removed, but a residue was observed in the surface of the substrate.
C: Any change was not observed in the surface of the film including the coating composition for producing the interlayer insulation film.

Formulations and evaluation results of Examples and Comparative Examples are listed in Table 1. Note that values in Table 1 are in weight ratios.

TABLE 1

| | | Exampl e 1 | Exampl e 2 | Exampl e 3 | Exampl e 4 | Exampl e 5 | Exampl e 6 | Comparati ve Example 1 | Comparati ve Example 2 | Comparati ve Example 3 | Comparati ve Example 4 | Comparati ve Example 5 |
|---|---|---|---|---|---|---|---|---|---|---|---|---|
| Polymerizab le compound | A-1 | 100 | | | | | 100 | | | | | |
| | A-2 | | 100 | | | | | | | | | |
| | A-3 | | | 100 | | | | | | | | |
| | A-4 | | | | 100 | 90 | | | | | | |
| | A′ -1 | | | | | | | 100 | | | | |
| | A′ | | | | | | | | 100 | | | |
| | -2 | | | | | | | | | | | |
| | A′ -3 | | | | | | | | | 100 | | |
| | A′ -4 | | | | | | | | | | 100 | |
| | A′ -5 | | | | | | | | | | | 100 |
| Monofunctional polymerizable monomer | | | | | | 10 | | | | | | |
| Pore-forming agent | | 10 | 10 | 10 | 10 | 10 | | 10 | | | | |
| Young’s modulus | | A | B | B | A | A | A | * | * | A | B | C |
| Relative dielectric constant | | A | B | B | A | A | B | | | C | B | B |
| Post-exposure delay stability | A | A | A | B | A | A | C | B | C | B | A | |
| Photo-curability | A | A | A | A | A | A | C | C | B | A | B | |
| Crack resistance | A | A | A | A | B | A | * | * | B | C | A | |
| Fine pattern formability | A | B | B | A | A | A | | | C | B | B | |
| Shrinkage | A | A | A | A | B | A | | | B | C | C | |
| Ease of washing | A | B | B | A | A | A | | | C | C | C | |

*Not photo-cured, thereby not measured.

### INDUSTRIAL APPLICABILITY

The coating composition for producing the interlayer insulation film according to the present invention can be used for interlayer insulation film production using various imprinting techniques. In particular, the coating composition can be preferably used as a coating composition for producing an interlayer insulation film to form a nano-sized fine pattern. Specifically, the coating composition can be used for producing a semiconductor integrated circuit, a micro-electromechanical system (MEMS), a sensor element, an optical disc, a magnetic recording medium such as a high-density memory disc, optical parts such as a diffraction grating and a relief hologram, a nano device, an optical device, an optical film and a polarizing element for producing flat panel displays, a thin-film transistor for liquid crystal displays, an organic transistor, a color filter, an overcoat layer, a micro-lens array, a immunoanalytical chip, a DNA separation chip, a microreactor, a nanobio device, an optical waveguide, an optical filter, a photonic liquid crystal, and a 3D printed object.

1. A method for producing an interlayer insulation film, the method comprising:
a step A of applying a coating composition for producing an interlayer insulation film onto a substrate, the coating composition including a polymerizable compound (A) and a photopolymerization initiator (B);
a step B of pressing an imprinting mold patterned with projections and depressions against a surface of the coating composition for producing an interlayer insulation film;
a step C of photo-curing the coating composition for producing an interlayer insulation film;
a step D of removing the imprinting mold; and
a step E of baking the coating composition for producing an interlayer insulation film at 250° C. or higher to form the interlayer insulation film, wherein
the polymerizable compound (A) is a polymerizable silicon compound having two or more polymerizable groups, at least one of the two or more polymerizable groups being a polymerizable group Q expressed by a formula (1) below , 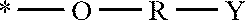
wherein
* represents a bond with a silicon atom,
R represents a single bond, an unsubstituted or substituted alkylene group having 1 to 12 carbon atoms and optionally containing a heteroatom, or a phenylene group, and
Y represents a polymerizable group.

2. The method for producing an interlayer insulation film according to claim 1, wherein the polymerizable group Y is an acryloyl group.

3. The method for producing an interlayer insulation film according to claim 1, wherein the polymerizable silicon compound (A) has three or more of the polymerizable groups Q.

4. The method for producing an interlayer insulation film according to claim 1, wherein an amount of silicon atoms in the polymerizable compound (A) is 10% by weight or more.

5. The method for producing an interlayer insulation film according to claim 1, wherein the coating composition for producing an interlayer insulation film includes a mold release agent.

6. The method for producing an interlayer insulation film according to claim 1, wherein the coating composition for producing an interlayer insulation film includes a pore-forming agent.

7. The method for producing an interlayer insulation film according to claim 1, wherein the coating composition for producing an interlayer insulation film includes a solvent.

8. The method for producing an interlayer insulation film according to claim 1, the method further comprising
a step F of, prior to the step B, pre-baking the coating composition for producing an interlayer insulation film on the substrate.

9-13. (canceled)

14. A method for producing a semiconductor element, the method comprising the method for producing an interlayer insulation film according to claim 1.

15. The method for producing an interlayer insulation film according to claim 2, wherein the polymerizable silicon compound (A) has three or more of the polymerizable groups Q.

16. The method for producing an interlayer insulation film according to claim 2, wherein an amount of silicon atoms in the polymerizable compound (A) is 10% by weight or more.

17. The method for producing an interlayer insulation film according to claim 3, wherein an amount of silicon atoms in the polymerizable compound (A) is 10% by weight or more.

18. The method for producing an interlayer insulation film according to claim 2, wherein the coating composition for producing an interlayer insulation film includes a mold release agent.

19. The method for producing an interlayer insulation film according to claim 3, wherein the coating composition for producing an interlayer insulation film includes a mold release agent.

20. The method for producing an interlayer insulation film according to claim 4, wherein the coating composition for producing an interlayer insulation film includes a mold release agent.

21. The method for producing an interlayer insulation film according to claim 2, wherein the coating composition for producing an interlayer insulation film includes a pore-forming agent.

22. The method for producing an interlayer insulation film according to claim 3, wherein the coating composition for producing an interlayer insulation film includes a pore-forming agent.

23. The method for producing an interlayer insulation film according to claim 2, wherein the coating composition for producing an interlayer insulation film includes a solvent.

24. The method for producing an interlayer insulation film according to claim 2, the method further comprising
a step F of, prior to the step B, pre-baking the coating composition for producing an interlayer insulation film on the substrate.

25. A method for producing a semiconductor element, the method comprising the method for producing an interlayer insulation film according to claim 2.
